(19) United States
(12) Patent Application Publication
(10) Pub. No.: US 2002/0079514 A1
(43) Pub. Date: Jun. 27, 2002

(54) Metal-oxide-semiconductor transistor structure and method of manufacturing same

(76) Inventors: Philip L. Hower, Concord, MA (US); Larry Wofford, Cary, NC (US)

Correspondence Address: TEXAS INSTRUMENTS INCORPORATED, P O BOX 655474, M/S 3999, DALLAS, TX, 75265

(21) Appl. No.: 10/061,140

(22) Filed: Oct. 25, 2001

Related U.S. Application Data
(60) Provisional application No. 60/258,892, filed on Dec. 27, 2000.

(51) Int. Cl. H01L 31/109

(52) U.S. Cl. 257/200

(57) ABSTRACT

According to one embodiment of the invention, method of manufacturing a metal-oxide-semiconductor transistor structure includes forming dielectric isolation regions in a semiconductor substrate, forming a first dielectric layer outwardly from the semiconductor substrate, forming a polysilicon layer outwardly from the first dielectric layer, etching a portion of the polysilicon layer to form a gate, and forming at least one notch in a first side of the gate. The method further includes etching a portion of the first dielectric layer to expose the semiconductor substrate, forming an n⁺ source region in the semiconductor substrate adjacent the first side of the gate, forming an n⁺ drain region in the semiconductor substrate adjacent a second side of the gate, and forming at least one p⁺ substrate contact region proximate the notch and adjacent the n⁺ source region.

### BACKGROUND OF THE INVENTION

Semiconductor devices are used for many applications, and one component used extensively in semiconductor devices is a transistor. There are many different types of transistors, including bipolar junction transistors. Bipolar junction transistors (“BJTs”) are used to make other types of transistors and devices, such as metal-oxide-semiconductor (“MOS”) transistors. Two such MOS transistors are NMOS and LDMOS.

Many factors are considered in manufacturing NMOS and LDMOS transistors. One such factor is the safe operating area (“SOA”) of the transistor. One phenomenon that adversely affects the SOA of NMOS and LDMOS transistors is avalanche injection. Avalanche injection occurs in NMOS and LDMOS transistors when a sufficient number of primary electrons due to channel current create secondary holes because of impact ionization. The holes drift in opposition to the electrons, moving towards the source and substrate regions. At a certain combination of channel current and drain multiplication, snapback occurs and normal device operation is interrupted with accompanying damage to the NMOS and LDMOS transistors. Snapback refers to the onset of negative resistance in the Id vs. Vds (or ID vs. Vgs) characteristic. Snapback defines the maximum boundary of Id-Vd points within which the transistor can operate without self-destruction. Accordingly, avalanche injection can hurt MOS performance, including reduction of the SOA. Therefore, semiconductor manufacturers desire methods of manufacturing NMOS and LDMOS transistors that improve the SOA by reducing the adverse effects of avalanche injection.

### SUMMARY OF THE INVENTION

The challenges in the field of semiconductor devices continue to increase with demands for more and better techniques having greater flexibility and adaptability. Therefore, a need has arisen for a new metal-oxide-semiconductor transistor structure and method of manufacturing same.

In accordance with the present invention, a method for manufacturing metal-oxide-semiconductor transistors is provided that addresses disadvantages and problems associated with previously developed methods.

According to one embodiment of the invention, method of manufacturing a metal-oxide-semiconductor transistor structure includes forming dielectric isolation regions in a semiconductor substrate, forming a first dielectric layer outwardly from the semiconductor substrate, forming a polysilicon layer outwardly from the first dielectric layer, etching a portion of the polysilicon layer to form a gate, and forming at least one notch in a first side of the gate. The method further includes etching a portion of the first dielectric layer to expose the semiconductor substrate, forming an n⁺ source region in the semiconductor substrate adjacent the first side of the gate, forming an n⁺ drain region in the semiconductor substrate adjacent a second side of the gate, and forming at least one p⁺ substrate contact region proximate the notch and adjacent the n⁺ source region.

According to one embodiment of the invention, a metal-oxide-semiconductor transistor structure includes a pair of dielectric isolation regions formed in a semiconductor substrate, a first dielectric layer disposed outwardly from the semiconductor substrate, a polysilicon layer disposed outwardly from the first dielectric layer, and a gate formed from etching the polysilicon layer. The gate has at least one notch formed in a first side. The structure also includes an n⁺ source region formed in the semiconductor substrate adjacent the first side of the gate, an n⁺ drain region formed in the semiconductor substrate adjacent a second side of the gate, and at least one p⁺ substrate contact region proximate the notch and adjacent the n⁺ source region.

Embodiments of the invention provide numerous technical advantages. For example, a technical advantage of one embodiment of the present invention is that the safe operating area (“SOA”) of NMOS and LDMOS transistors is improved by reducing the adverse effects of snapback induced by avalanche injection.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIG. 1A is a plan view, and FIGS. 1B and 1C are elevation views, of a portion of a semiconductor device having a partially-completed metal-oxide-semiconductor transistor structure manufactured according to the teachings of the present invention; and

FIGS. 2 through 6 are a series of cross-sectional views illustrating various manufacturing stages of the partially-completed metal-oxide-semiconductor transistor structure of FIGS. 1A, 1B, and 1C.

### DETAILED DESCRIPTION OF EXAMPLE EMBODIMENTS OF THE INVENTION

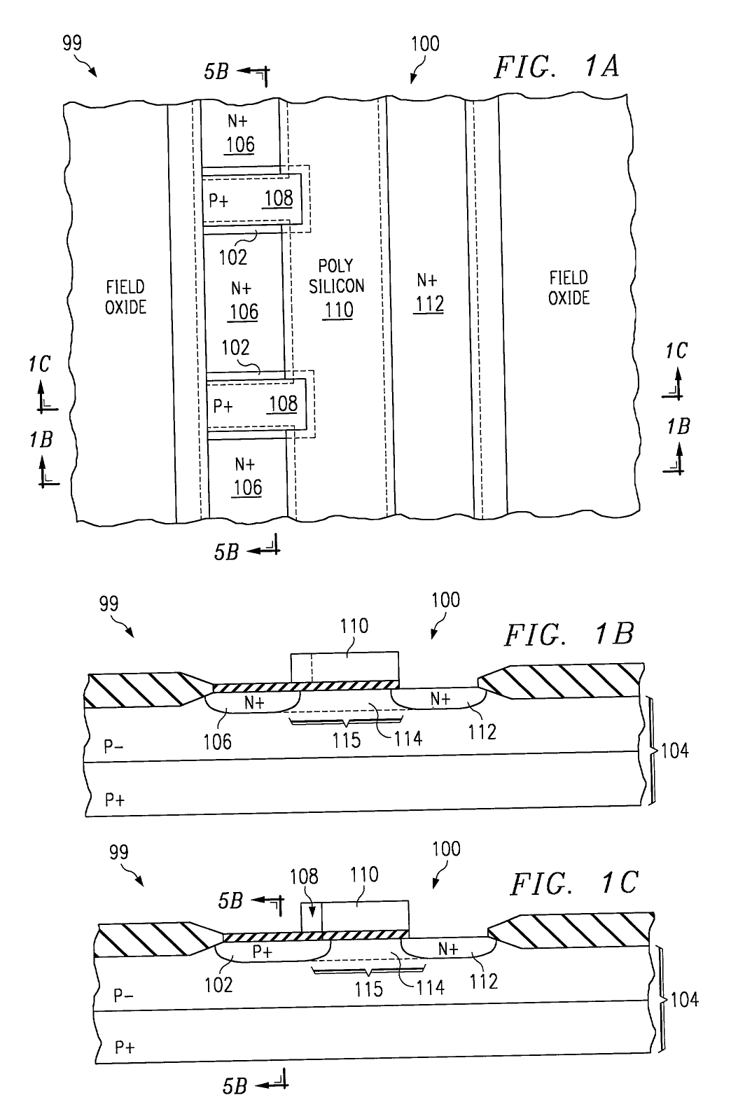

Example embodiments of the present invention and their advantages are best understood by referring now to FIGS. 1A through 6 of the drawings, in which like numerals refer to like parts.

FIG. 1A is a plan view, and FIGS. 1B and 1C are elevation views, of a portion of a semiconductor device 99 having a partially-completed metal-oxide-semiconductor (“MOS”) transistor 100 manufactured according to the teachings of the present invention. MOS transistor 100 is shown in FIGS. 1A, 1B and 1C to be an NMOS transistor. However, MOS transistor 100 may also be other types of transistors, such as an LDMOS transistor.

Many factors are considered in manufacturing MOS transistors. One such factor is the safe operating area of the transistor. One phenomenon that adversely affects the safe operating area of MOS transistors is avalanche injection, which occurs when a sufficient number of primary electrons due to channel current create secondary holes because of impact ionization. The holes drift in opposition to the electrons, moving toward the source and substrate regions. At a certain combination of channel current and drain multiplication, “snapback” occurs and normal transistor operation is interrupted with accompanying damage to the MOS transistor. Snapback refers to the onset of negative resistance in the Id vs. Vds (or ID vs. Vgs) characteristic. Accordingly, avalanche injection hurts performance, including a reduction in the safe operating area.

As illustrated in FIGS. 1A, 1B, and 1C, the present invention addresses the problem of avalanche injection, and others, by providing at least one P⁺ substrate contact region 102 to act as a “hole collector” for MOS transistor 100. P⁺ substrate contact regions 102 act as shunts and attract undesirable holes to keep them from migrating into an N⁺ source region 106, where the holes can initiate bipolar transistor action of the parasitic NPN transistor formed by N⁺ source region 102, a P-type substrate, and an N⁺ drain region 112, acting as Emitter, Base, and Collector, respectively. The shunting of hole current in this manner improves the safe operating area of MOS transistor 100. P⁺ substrate contact regions 102, which are discussed in greater detail below in conjunction with FIGS. 5A and 5B, are formed in a semiconductor substrate 104 proximate notches 108 in a gate 110 of MOS transistor 100. Notches 108 are discussed in greater detail below in conjunction with FIGS. 3A and 3B.

FIGS. 1B and 1C show MOS transistor 100 at different cross-sections indicated by section lines 1B-1B and 1C-1C of FIG. 1A. Those skilled in the art of semiconductors recognize that the cross-section shown in FIG. 1B is a standard cross-section of a partially-completed NMOS transistor having N⁺ source region 106, gate 110, N⁺ drain region 112, and a channel region 114 existing between N⁺ source region 106 and N⁺ drain region 112. Channel 114 has a channel length 115 associated therewith. Channel 114 is where electrons flow from N⁺ source region 106 to N⁺ drain region 112 during MOS transistor 100 operation. In addition, channel 114 is where the undesirable holes, due to avalanche injection, drift from N⁺ drain region 112 to N⁺ source region 106. To direct these undesirable holes away from N⁺ source region 106, P⁺ substrate contact regions 102 are formed in semiconductor substrate 104 as shown best in FIG. 1C.

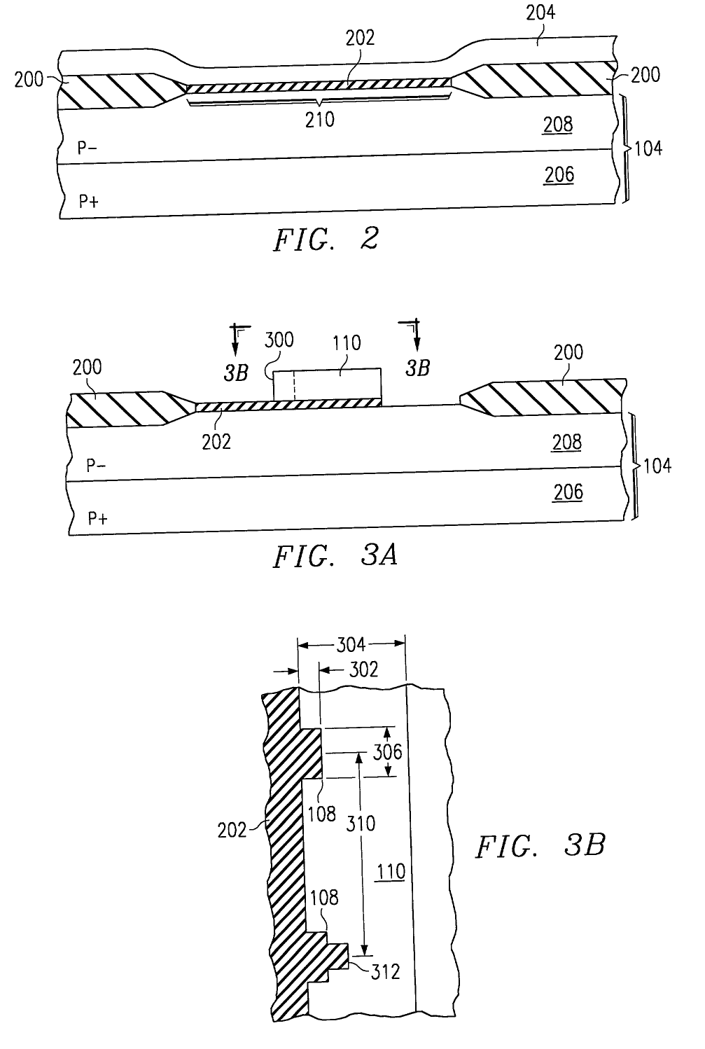

FIG. 1C is a cross-section of MOS transistor 100 at a location where P⁺ substrate contact regions 102 exist. As illustrated, P⁺ substrate contact region 102 is formed in semiconductor substrate 104 on the source side of MOS transistor 100 proximate notch 108. Comparing FIGS. 1B and 1C shows that P⁺ substrate contact region 102 has a greater length than N⁺ source region 106. This means that channel 114 has a shorter channel length 115 in the area where P⁺ substrate contact regions 102 exist. This shorter channel length 115 facilitates the attracting of holes created because of avalanche injection as described above. P⁺ substrate contact regions 102 keep the undesirable holes from migrating into N⁺ source region 106. Various manufacturing stages of MOS transistor 104 describing how P⁺ substrate contact regions 102 are created are shown in FIGS. 2-6.

FIG. 2 shows semiconductor substrate 104 having a pair of dielectric isolation regions 200 formed therein, a first dielectric layer 202 disposed outwardly from semiconductor substrate 104, and a polysilicon layer 204 disposed outwardly from first dielectric layer 202. Semiconductor substrate 104 is formed from any suitable type of semiconductor material, such as single crystal silicon. Semiconductor substrate 104, in one embodiment, has a buried P⁺ region 206 and a P⁻ region 208. However, semiconductor substrate 104 can have any number of doped or undoped regions depending on the type of transistor being manufactured. For example, in an n-channel LDMOS transistor, MOS transistor 100 may have an N-well diffused in P⁻ region 208, and a P-body diffused in the N-well and disposed beneath N⁺ source region 106 and P⁺ substrate contact region 102.

Dielectric isolation regions 200 are, in one embodiment, oxide regions formed using LOCOS techniques well known in the art of semiconductor processing; however, isolation regions 200 may be formed using other methods, such as a shallow trench isolation process. Dielectric isolation regions 200 may be formed from any suitable type of dielectric material, such as other oxides or nitrides. Dielectric isolation regions 200 function to define an active area 210 therebetween, and serve to isolate adjacent transistors formed in semiconductor device 99.

Dielectric layer 202, in one embodiment, is formed from oxide; however, dielectric layer 202 may be formed from any suitable type of dielectric material. In one embodiment, dielectric layer 202 is approximately 370 Å; however, dielectric layer 202 may be any suitable thickness. In the embodiment shown in FIG. 2, dielectric layer 202 is formed using any suitable growth or deposition techniques conventionally used in semiconductor processing.

Polysilicon layer 204 is polycrystalline silicon used to form gate 110 of MOS transistor 100. In one embodiment, polysilicon layer 204 is approximately 6000 Å. However, polysilicon layer 204 may be any suitable thickness and may be formed using any suitable layering techniques conventionally used in semiconductor processing.

FIG. 3A shows gate 110 formed by etching polysilicon layer 204 using any suitable etching techniques well known in the art of semiconductor processing. According to the teachings of the present invention, gate 110 has at least one notch 108 formed in a first side 300 of gate 110. Two such notches 108 are shown in plan view in FIG. 3B. Notches 108 function to define areas in semiconductor substrate 104 for forming P⁺ substrate contact regions 102, which are described in detail below in conjunction with FIGS. 5A and 5B.

Referring to FIG. 3B, notches 108 are formed with a notch length 302 between approximately 0.2 and 0.4 times a length 304 of gate 110, and a notch width 306 between approximately two and six micrometers. In one embodiment, notches 108 are formed with notch length 302 of approximately 0.3 times length 304 of gate 110, and notch width 306 of approximately one times length 304 of gate 110, which in one embodiment is three micrometers. As illustrated in FIG. 3B, gate 110 may be formed with a plurality of notches 108 along a width 308 of gate 110. If plurality of notches 108 exist, then plurality of notches 108, in one embodiment, are spaced at a distance 310 between approximately 1.5 to 3.0 times length 304 of gate 110. In an alternative embodiment, plurality of notches 108 are spaced at distance 310 of approximately two times length 304 of gate 110.

In addition to notches 108, an additional notch 312 may be formed in one or more of notches 108 to further the teachings of the present invention. In an alternative embodiment, a plurality of additional notches 312 may be formed in any of notches 108. Additional notches 312 have similar dimensions to notches 108 as described above and can be utilized until lithography introduces limits or a distance is reached such that the field at N⁺ drain region 112 exceeds a critical value Ecp, which is approximately twice the value of Ecn that initiates snapback.

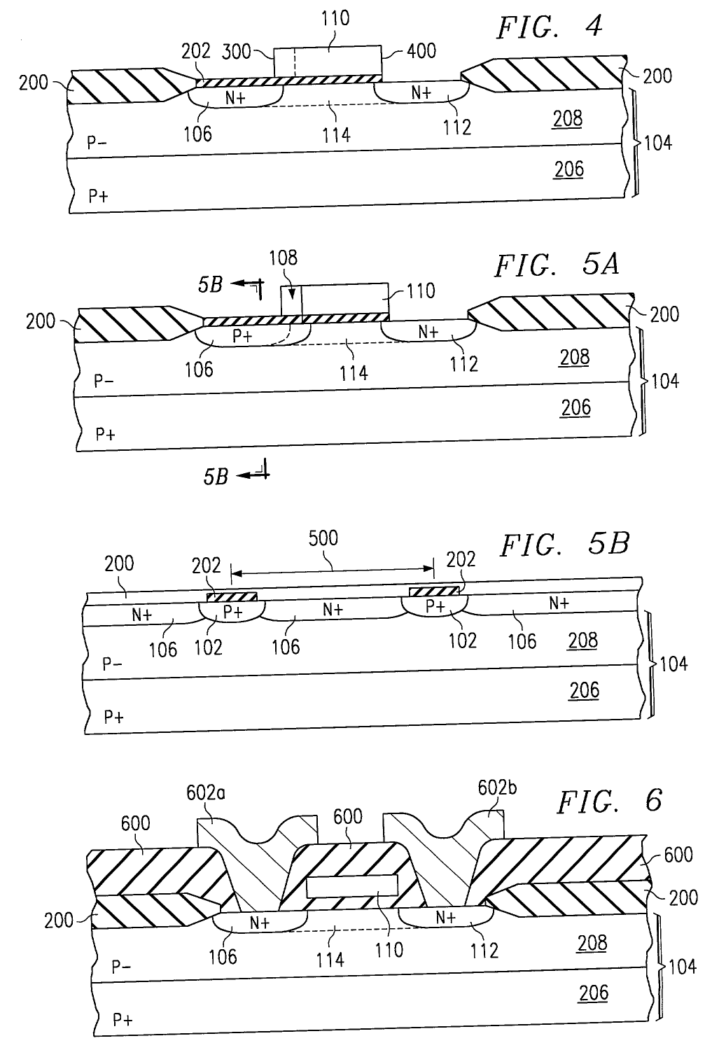

FIG. 4 shows N⁺ source region 106 formed in semiconductor substrate 104 adjacent first side 300 of gate 110, and N⁺ drain region 112 formed in semiconductor substrate 104 adjacent a second side 400 of gate 110. Both N⁺ source region 106 and N⁺ drain region 112 are formed by implanting an N-type dopant, such as arsenic, phosphorus, or antimony, in semiconductor substrate 104 using any suitable implantation process. As shown best in FIG. 1A, N⁺ source region 106 is interrupted along width 308 of gate 110 by P⁺ substrate contact regions 102, which are discussed below in conjunction with FIGS. 5A and 5B. To implant an N-type dopant in semiconductor substrate 104, portions of first dielectric layer 202 are removed. These portions define the boundaries of N⁺ source region 106, and are removed using any suitable etching techniques well known in the art of semiconductor processing. Some of first dielectric layer 202 remains adjacent first side 300 of gate 110 as shown best in FIG. 1A. These remaining areas of first dielectric layer 202 are where P⁺ substrate contact regions 102 are implanted as discussed further below.

FIGS. 5A and 5B show P⁺ substrate contact regions 102 proximate notch 108 and adjacent N⁺ source region 106. There may be one or any suitable number of P⁺ substrate contact regions 102. P⁺ substrate contact regions 102 are formed by implanting a P-type dopant, such as boron, in semiconductor substrate 104 using any suitable implantation process.

As discussed above in conjunction with FIGS. 1A, 1B, and 1C, according to the teachings of the present invention, P⁺ substrate contact regions 102 act as “hole collectors” for MOS transistor 100. Because of a phenomenon known as avalanche injection, secondary holes are created from impact ionization of a sufficient number of primary electrons due to channel current. P⁺ substrate contact regions 102 attract these holes to keep them from migrating into N⁺ source region 106, thereby improving the safe operating area of MOS transistor 100.

As shown in FIG. 5B, P⁺ substrate contact regions 102, in one embodiment, are spaced at a distance 500 between approximately 1.5 to 3.0 times length 304 of gate 110. In an alternative embodiment, P⁺ substrate contact regions 102 are spaced at distance 500 of approximately two times length 304 of gate 110.

FIG. 6 shows a substantially-completed MOS transistor 100 in accordance with one embodiment of the present invention. Referring to FIG. 6, MOS transistor 100 is substantially completed through the forming of a second dielectric layer 600 and the forming of N⁺ source contact 602a and N⁺ drain contact 602b. Second dielectric layer 600 may comprise, for example, a layer of dielectric material, such as non-doped silicon glass (“NSG”) and a layer of borophosphorus silicate glass (“BPSG”), which is deposited in the outer surfaces of the structures formed previously to a thickness on the order of 9000 Å. Other suitable thicknesses may also be used for second dielectric layer 600. Conventional photolithographic techniques are then used to form openings within dielectric layer 600 so that N⁺ source contact 602a and N⁺ drain contact 602b can be formed.

N⁺ source contact 602a and N⁺ drain contact 602b are formed by the deposition of conductive material within the formed openings in second dielectric layer 600. N⁺ source contact 602a and N⁺ drain contact 602b may comprise a suitable metal conductor, such as copper or aluminum. N⁺ source contact 602a and N⁺ drain contact 602b are formed by patterning and etching using conventional photolithographic and metal etching techniques, which substantially completes MOS transistor 100.

Although embodiments of the invention and their advantages are described in detail, a person skilled in the art could make various alternations, additions, and omissions without departing from the spirit and scope of the present invention as defined by the appended claims.

What is claimed is:

1. A method of manufacturing a metal-oxide-semiconductor transistor structure, comprising:
forming a plurality of dielectric isolation regions in a semiconductor substrate;
forming a first dielectric layer outwardly from the semiconductor substrate;
forming a polysilicon layer outwardly from the first dielectric layer;
etching a portion of the polysilicon layer to form a gate;
forming at least one notch in a first side of the gate;
etching a portion of the first dielectric layer to expose the semiconductor substrate;
forming an n⁺ source region in the semiconductor substrate adjacent the first side of the gate;
forming an n⁺ drain region in the semiconductor substrate adjacent a second side of the gate; and
forming at least one p⁺ substrate contact region proximate the notch and adjacent the n⁺ source region.

2. The method of claim 1, wherein forming at least one notch in the first side of the gate comprises forming the notch with a length between approximately 0.2 and 0.4 times a length of the gate.

3. The method of claim 1, wherein forming at least one notch in the first side of the gate comprises forming the notch with a length of approximately 0.3 times a length of the gate.

4. The method of claim 1, wherein forming at least one notch in the first side of the gate comprises forming the notch with a width between approximately two and six micrometers.

5. The method of claim 1, wherein forming at least one notch comprises forming a plurality of notches along a width of the gate.

6. The method of claim 5, wherein forming the plurality of notches along the length of the gate comprises spacing the plurality of notches at a distance between approximately 1.5 to 3.0 times the length of the gate.

7. The method of claim 1, further comprising forming an additional notch in the at least one notch.

8. The method of claim 1, further comprising forming a plurality of additional notches in the at least one notch.

9. A method of manufacturing a metal-oxide-semiconductor transistor structure, comprising:
forming a plurality of dielectric isolation regions in a semiconductor substrate;
forming a first dielectric layer outwardly from the semiconductor substrate;
forming a polysilicon layer outwardly from the first dielectric layer;
etching a portion of the polysilicon layer to form a gate;
forming a plurality of notches in a first side of the gate, each notch having a length between approximately 0.2 and 0.4 times a length of the gate;
etching a portion of the first dielectric layer to expose the semiconductor substrate;
forming an n⁺ source region in the semiconductor substrate adjacent the first side of the gate;
forming an n⁺ drain region in the semiconductor substrate adjacent a second side of the gate; and
forming a plurality of p⁺ substrate contact regions proximate each notch and adjacent the n⁺ source region.

10. The method of claim 9, wherein forming the plurality of notches in the first side of the gate comprises forming each notch with a length of approximately 0.3 times the length of the gate.

11. The method of claim 9, wherein forming the plurality of notches in the first side of the gate comprises forming each notch with a width between approximately two and six micrometers.

12. The method of claim 9, wherein forming the plurality of notches in the first side of the gate comprises spacing the plurality of notches at a distance between approximately 1.5 to 3.0 times the length of the gate.

13. The method of claim 9, further comprising forming an additional notch in at least one of the plurality of notches.

14. A metal-oxide-semiconductor transistor structure, comprising:
a pair of dielectric isolation regions formed in a semiconductor substrate;
a first dielectric layer disposed outwardly from the semiconductor substrate;
a polysilicon layer disposed outwardly from the first dielectric layer;
a gate formed from etching the polysilicon layer, the gate having at least one notch formed in a first side;
an n⁺ source region formed in the semiconductor substrate adjacent the first side of the gate;
an n⁺ drain region formed in the semiconductor substrate adjacent a second side of the gate; and
at least one p⁺ substrate contact region proximate the notch and adjacent the n⁺ source region.

15. The structure of claim 14, wherein the notch is formed with a length between approximately 0.2 and 0.4 times a length of the gate.

16. The structure of claim 14, wherein the notch is formed with a length of approximately 0.3 times a length of the gate.

17. The structure of claim 14, wherein the notch is formed with a width between approximately two and six micrometers.

18. The structure of claim 14, wherein the gate is formed with a plurality of notches along a width of the gate, the plurality of notches spaced at a distance between approximately 1.5 to 3.0 times the length of the gate.

19. The structure of claim 14, further comprising an additional notch formed in the at least one notch.

20. The structure of claim 14, further comprising a plurality of additional notches formed in the at least one notch.
